(19) United States
(12) Patent Application Publication
(10) Pub. No.: US 2026/0175122 A1
(43) Pub. Date: Jun. 25, 2026

(54) OPERATION DEVICE

(71) Applicant: Sony Interactive Entertainment Inc., Tokyo (JP)

(72) Inventor: Shoki Kishida, Tokyo (JP)

(21) Appl. No.: 19/543,642

(22) Filed: Feb. 18, 2026

Related U.S. Application Data
(63) Continuation of application No. PCT/JP2023/031605, filed on Aug. 30, 2023.

(51) Int. Cl. A63F 13/24; A63F 13/235; A63F 13/92; H02J 7/35; H02S 20/30; H02S 40/36; H02S 40/38; H10F 19/90

(52) U.S. Cl. CPC A63F 13/24; A63F 13/235; A63F 13/92; H02J 7/35; H02S 20/30; H02S 40/36; H02S 40/38; H10F 19/902; A63F 2300/1043; A63F 2300/105

(57) ABSTRACT

The operation device 6 is provided with a gripping portion which the user holds with a hand and an input unit that the user operates. In the operation device 6, a plurality of photovoltaic elements 110 are arranged in a housing, and the power storage unit 112 stores the power generated by the plurality of photovoltaic elements 110.

### CROSS-REFERENCE TO RELATED APPLICATIONS

This application is a Continuation of International Application No. PCT/JP2023/031605, having an International Filing Date of Aug. 30, 2023. This disclosure of the prior application is considered part of the disclosure of this application.

### FIELD

The present disclosure relates to an operation device having an input unit that a user operates.

### BACKGROUND

When a battery-powered game controller runs out of power, the battery needs to be replaced or recharged.

Therefore, if there is no battery for replacement or no charger or external power source to charge the battery, the game controller will not be able to get enough power and cannot be operated.

### SUMMARY

The present disclosure has been made in consideration of the above circumstances, and its purpose is to provide technology relating to operation devices such as game controllers that do not have secondary batteries that are charged by an external power source or primary batteries (disposable batteries).

An operation device according to one aspect of the present disclosure is an operation device that includes a gripping portion that is held by a user's hand and an input unit that a user operates, and also includes a plurality of photovoltaic elements arranged in a housing, and a power storage unit that stores the power generated by the plurality of photovoltaic elements.

Any combination of the above constituent elements, or interchangeable conversions between recording data, data structures, or the like that record the present disclosure, including a system, a computer program, a recording medium storing a computer program, is also valid as an aspect of the present disclosure.

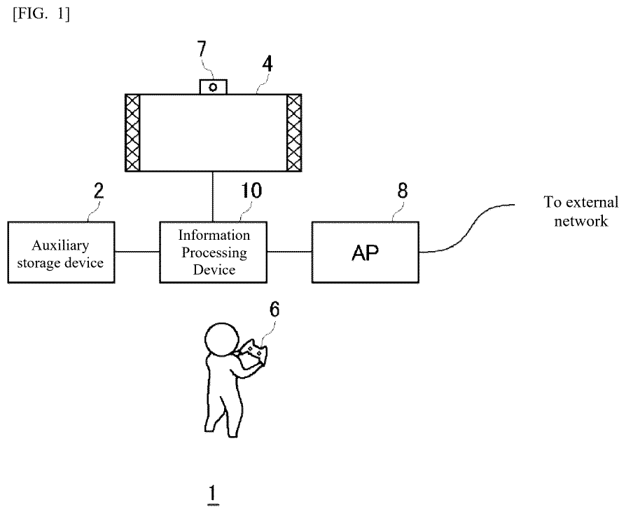

FIG. 1 is a diagram illustrating an information processing system according to an example.

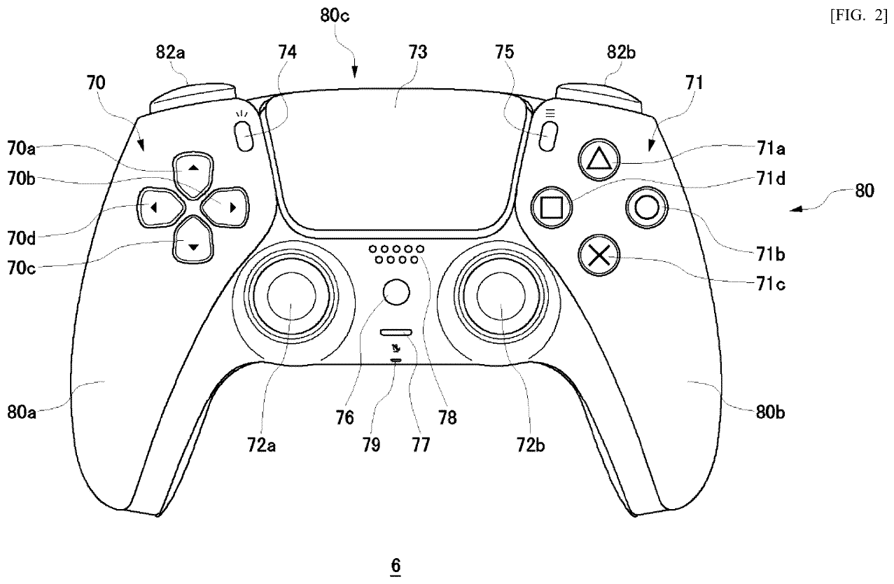

FIG. 2 is a top view of the operation device.

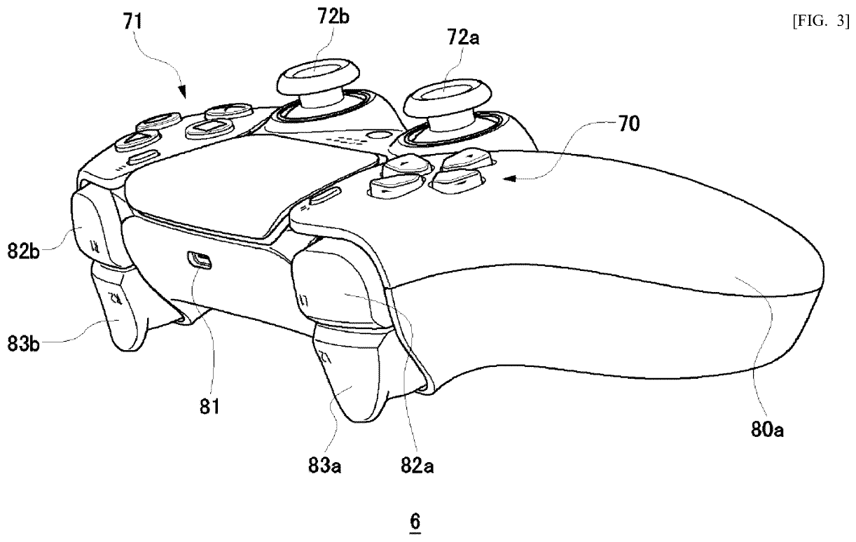

FIG. 3 is a perspective view of the operation device.

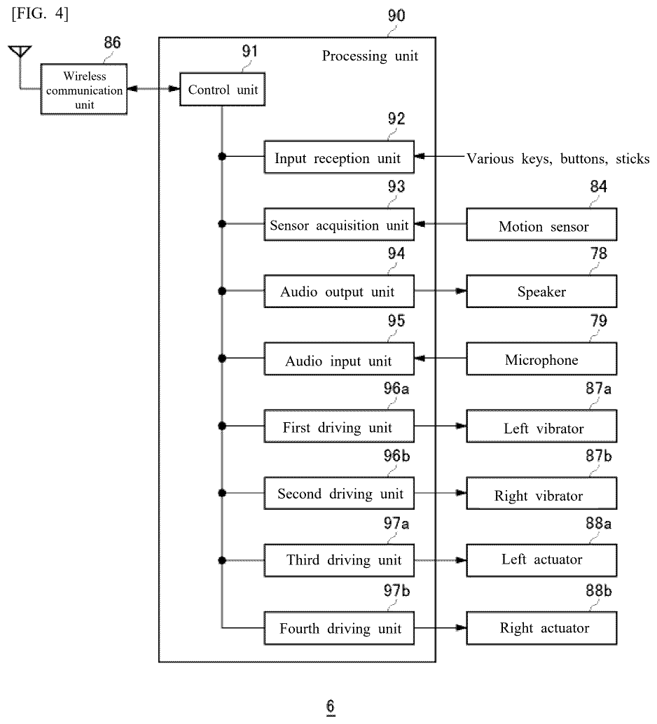

FIG. 4 is a diagram showing functional blocks related to the motion of the operation device

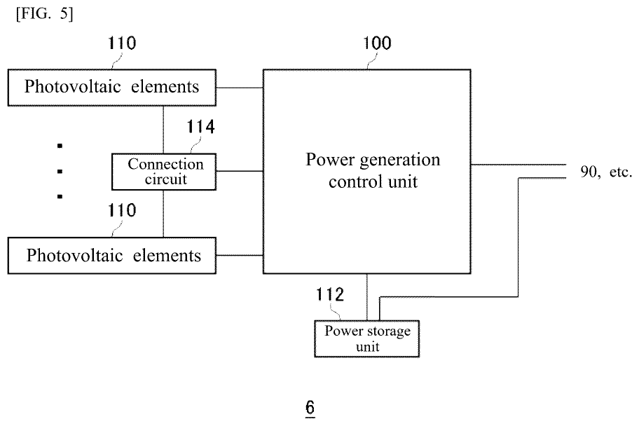

FIG. 5 is a diagram showing functional blocks related to the power generation of the operation device.

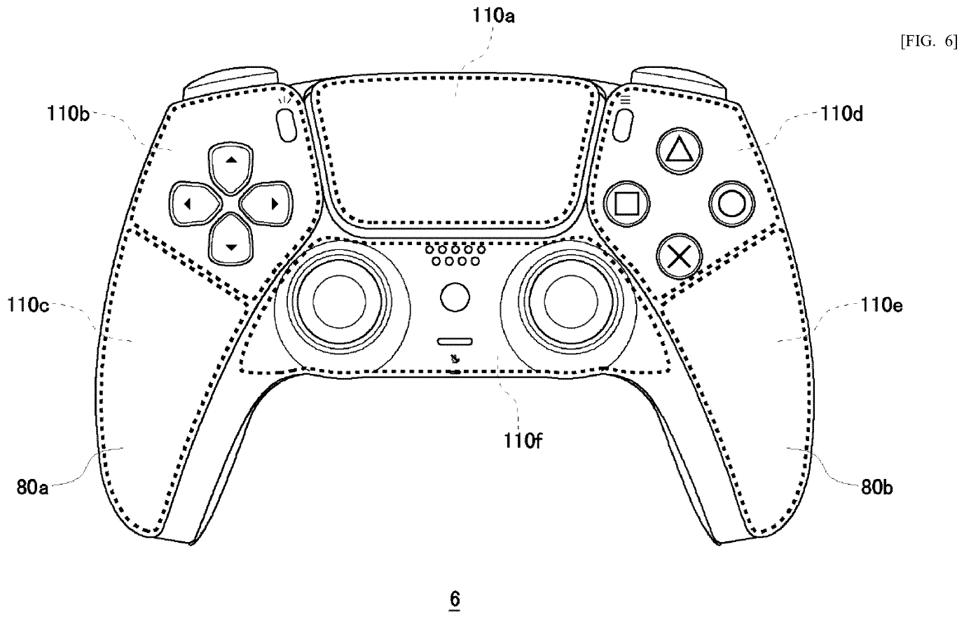

FIG. 6 is a diagram showing an example of a plurality of photovoltaic elements arranged in a housing.

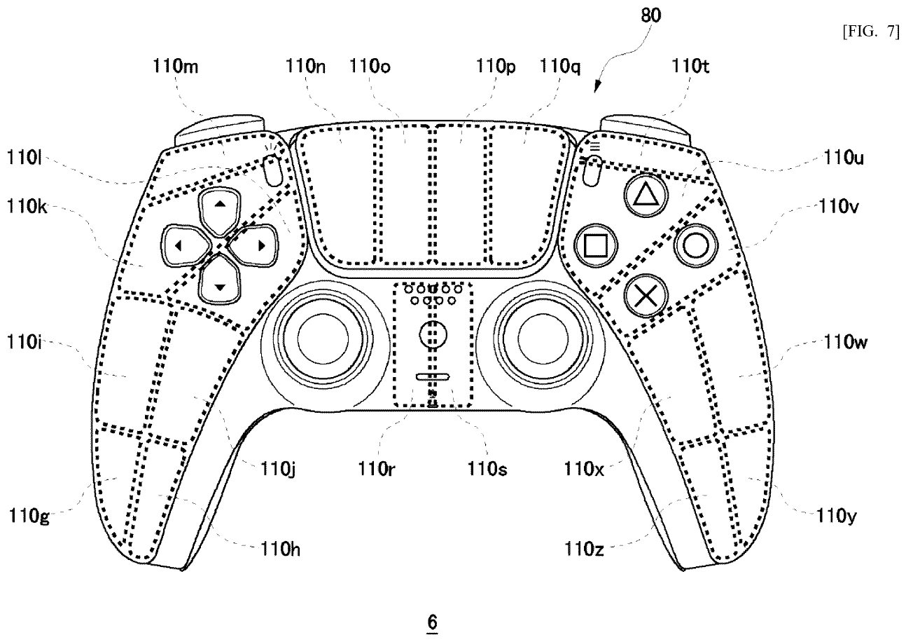

FIG. 7 is a diagram showing another example of a plurality of photovoltaic elements arranged in a housing.

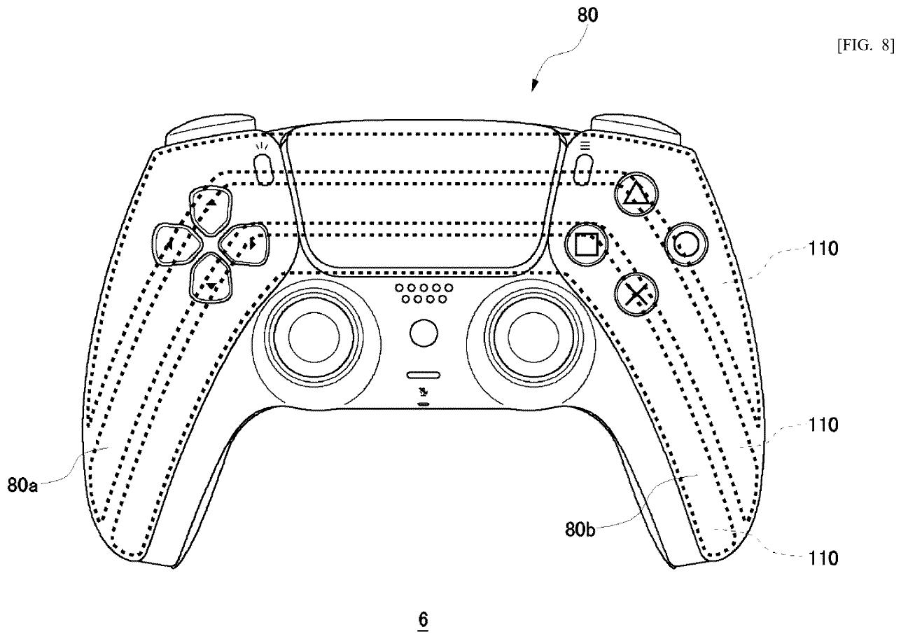

FIG. 8 is a diagram showing another example of a plurality of photovoltaic elements arranged in a housing.

### DETAILED DESCRIPTION

FIG. 1 illustrates an information processing system 1 according to an example of the present disclosure. The information processing system 1 is provided with an information processing device 10 that is an user terminal device, an auxiliary storage device 2, an output device 4, and an operation device 6. The operation device 6 is provided with a gripping portion that is held by the user's hand and an input unit that a user operates. An access point (hereinafter referred to as “AP”) 8 has the functions of a wireless access point and a router, and the information processing device 10 is connected to the AP 8 wirelessly or via a wired connection. The information processing device 10 is connected to an external network such as the Internet via the AP 8, and is connected to a server device (not illustrated) so as to be able to communicate with the network.

The information processing device 10 is connected wirelessly or via a wired connection to an operation device 6 operated by the user, and the operation device 6 transmits data operated by the user A to the information processing device 10. When receiving operation data from the operation device 6, the information processing device 10 reflects the data in system software and game software processing, and outputs processing results from an output device 4.

In the example, the information processing device 10 is a game device (game console) that executes a game, and the operation device 6 is an electronic device that provides operation information obtained through the user operating the input unit to the information processing device 10. The operation device 6 may be a game controller. The information processing device 10 executes a game program based on the operation information of the user and generates images and sound of the game to be output from the output device 4. Further, in the information processing system 1, the server device may execute the game program based on the operation information of the user to generate the image and sound of the game. In this case, the information processing device 10 operates as a client device that transmits operation information of the user to the server device, receives images and sound generated by the server device, and outputs them from the output device 4.

The auxiliary storage device 2 is a large-capacity recording device such as an HDD (hard disk drive) or an SSD (solid state drive), and may be a built-in recording device or an external recording device that is connected to the information processing device 10 via a USB (universal serial bus) or the like. The output device 4 may be a television that has a display device that outputs an image and a speaker that outputs sound. The output device 4 may be connected to the information processing device 10 by a wired cable, or may be connected wirelessly.

A camera 7 serving as an imaging device is provided in a vicinity of the output device 4 and captures an image of a space around the output device 4. FIG. 1 illustrates an example in which the camera 7 is mounted on a top portion of the output device 4, but such may be disposed on a side or bottom portion of the output device 4, and in any case, is disposed in a position in which an image of the user positioned in front of the output device 4 may be captured. The camera 7 may also be a stereo camera.

FIG. 2 shows a top view of the operation device, and FIG. 3 shows a perspective view of the operation device. The operation device 6 includes a housing 80 comprising a left gripping portion 80a, a right gripping portion 80b, and a housing main body portion 80c. The left gripping portion 80a and the right gripping portion 80b are provided on either side of the housing main body portion 80c, and the left gripping portion 80a is gripped by the user's left hand, and the right gripping portion 80b is gripped by the user's right hand. Vibrators for providing a tactile sensation to the user's hands are provided in the internal spaces at the ends of the left gripping portion 80a and the right gripping portion 80b.

Operation buttons that are operated by the user is disposed on the housing main body portion 80c. The top surface of the housing main body portion 80c is provided with directional keys 70, action buttons 71, a left analog stick 72a, a right analog stick 72b, a touchpad 73, a create button 74, an option button 75, a home button 76, a mute button 77, a speaker 78, and a microphone 79. The direction keys 70 are made up of an up key 70a, a right key 70b, a down key 70c, and a left key 70d, and the action buttons 71 are made up of a Δ button 71a, a ◯ button 71b, an x button 71c, and a □ button 71d. The left analog stick 72a also functions as an L3 button that is turned on when pressed, and similarly the right analog stick 72b also functions as an R3 button that is turned on when pressed. The touchpad 73 also functions as a touchpad button that is turned on when pressed.

The back surface of the housing main body 80 c is provided with a USB terminal 81, an L1 button 82a, an R1 button 82b, an L2 button 83a, and an R2 button 83b. The L2 button 83a and the R2 button 83b are trigger-type buttons, and are connected to actuators that dynamically change the resistance when the user presses the trigger-type buttons with their fingers. For example, the pressing resistance of the L2 button 83a and/or R2 button 83b can be dynamically changed depending on the action being taken in the game, thereby enhancing the sense of realism of the game.

FIG. 4 shows functional blocks of the motion of the operation device. The operation device 6 includes, inside the housing 80, a wireless communication unit 86, a processing unit 90, a motion sensor 84, a speaker 78, a microphone 79, a left vibrator 87a, a right vibrator 87b, a left actuator 88a, and a right actuator 88b. The wireless communication unit 86 has a function of transmitting and receiving data to and from the wireless communication unit of the information processing device 10.

The processing unit 90 has a control unit 91, an input reception unit 92, a sensor data acquisition unit 93, an audio output unit 94, an audio input unit 95, a first driving unit 96a, a second driving unit 96b, a third driving unit 97a, and a fourth driving unit 97b. The control unit 91 performs various processes in the operation device 6.

The input reception unit 92 receives operation information of the user from an input unit such as direction keys 70, action buttons 71, a left analog stick 72a, a right analog stick 72b, a touchpad 73, a create button 74, an option button 75, a home button 76, a mute button 77, an L1 button 82a, an R1 button 82b, an L2 button 83a, and an R2 button 83b, and sends such to the control unit 91. The control unit 91 supplies the received operation information to the wireless communication unit 86, and the wireless communication unit 86 transmits the operation information to the information processing device 10.

The motion sensor 84 includes a three-axis acceleration sensor and a three-axis gyro sensor. The three-axis acceleration sensor detects acceleration in three axes of x, y and z, and the three-axis gyro sensor detects angular velocities in the xz plane, zy plane and yx plane. The three-axis acceleration sensor and the three-axis gyro sensor may be disposed at a position near the center of the housing 80. The motion sensor 84 detects acceleration and angular velocity at a predetermined cycle. When the sensor data acquisition unit 93 acquires the sensor data detected by the motion sensor 84, the control unit 91 supplies the sensor data to the wireless communication unit 86, and the wireless communication unit 86 transmits the sensor data to the information processing device 10.

When the wireless communication unit 86 receives the audio data from the information processing device 10, the control unit 91 supplies the audio data to the audio output unit 94, and the audio output unit 94 outputs the audio from the speaker 78. When the audio input unit 95 receives audio data of the user from the microphone 79, the control unit 91 supplies the audio data of the user to the wireless communication unit 86, and the wireless communication unit 86 transmits the audio data of the user to the information processing device 10. The operation device 6 is provided with a speaker 78 and a microphone 79, allowing the user to enjoy audio chat with friends.

The left vibrator 87a is built into the protruding end of the left gripping portion 80a, and the right vibrator 87b is built into the protruding end of the right gripping portion 80b. The left vibrator 87a and the right vibrator 87b (hereinafter, sometimes referred to as “vibrators 87” when no particular distinction is made) are built into the end of the grip portion that is held by the user's hand, making it possible to present a tactile sensation to the user's hand. The vibrators 87 may be configured with a vibration motor having an eccentric weight.

When the wireless communication unit 86 receives a control signal for the left vibrator 87a and a control signal for the right vibrator 87b from the information processing device 10, it supplies the control signals to the control unit 91, and the control unit 91 controls the first driving unit 96a based on the control signal for the left vibrator 87a and controls the second driving unit 96b based on the control signal for the right vibrator 87b. The first driving unit 96a and the second driving unit 96b may be configured as PWM control units that vary the duty ratio of the voltages supplied to the left vibrator 87a and the right vibrator 87b, respectively.

The left actuator 88a is connected to the L2 button 83a, and the right actuator 88b is connected to the R2 button 83b. The left actuator 88a and the right actuator 88b (hereinafter sometimes referred to as “actuators 88” when no particular distinction is made) apply resistance to the user's fingers pressing the L2 button 83a and the R2 button 83b, respectively. The actuators 88 have a structure that applies a resistance force against the pressing force of the L2 button 83a and the R2 button 83b.

When the wireless communication unit 86 receives from the information processing device 10 a control signal for the left actuator 88a and a control signal for the right actuator 88b, it supplies the control signals to the control unit 91, and the control unit 91 controls the third driving unit 97a based on the control signal for the left actuator 88a and controls the fourth driving unit 97b based on the control signal for the right actuator 88b. The third driving unit 97a and the fourth driving unit 97b may be configured as PWM control units that vary the duty ratio of the voltages supplied to the left actuator 88a and the right actuator 88b, respectively.

The operation device 6 of the example includes a plurality of photovoltaic elements having a solar photovoltaic generation. The configuration (electronic components) shown as functional blocks in FIG. 4 is driven by the power generated by the photovoltaic element.

FIG. 5 shows functional blocks related to the power generation of the operation device. The operation device 6 has a power generation control unit 100, a power storage unit 112 and a connection circuit 114 inside a housing 80, and has a plurality of photovoltaic elements 110 on the surface of the housing 80. The photovoltaic element 110 may form the outer surface of the housing 80, but may also be provided inside the transparent resin that forms the outer periphery of the housing 80. In either case, the photovoltaic element 110 is provided in the housing 80 so as to be irradiated with light.

The operation device 6 includes a computer, and various functions are realized by the computer executing a program. A computer includes, as hardware, a memory into which programs are loaded, one or more processors that execute the loaded programs, an auxiliary storage device, other LSIs, and the like. The processor is composed of a plurality of electronic circuits including semiconductor integrated circuits and LSIs, and the plurality of electronic circuits may be mounted on a single chip or on a plurality of chips. The functional blocks shown in FIG. 4 and FIG. 5 are realized through integration of hardware and software, and therefore apparent to those skilled in the art that these functional blocks can be implemented in various ways using hardware only, using software only, or using a combination of hardware and software.

The operation device 6 of the example does not include a secondary battery that is charged by an external power source, such as a commercial power source, or a primary battery. In the operation device 6, the photovoltaic element 110 has a solar photovoltaic generation function and generates the power used in the operation device 6. The power storage unit 112 is a capacitor that stores the power generated by the plurality of photovoltaic elements 110. The configuration (electronic component) illustrated as the functional blocks in FIGS. 4 and 5 is driven using the power stored in the power storage unit 112. The operation device 6 has an advantage of not having to equip a secondary battery charged by an external power source or a primary battery by providing a plurality of photovoltaic elements 110.

FIG. 6 illustrates an example of a plurality of photovoltaic elements disposed in a housing. In the example shown in FIG. 6, a plurality of photovoltaic elements 110a, 110b, 110c, 110d, 110e, and 110f (hereinafter simply referred to as “photovoltaic elements 110” when no particular distinction is made) are arranged on the upper surface of the housing 80 so as to be efficiently exposed to light. One photovoltaic element 110 is a single component that is integrally formed, and the plurality of photovoltaic elements 110 are arranged on the top surface of the housing 80 so as not to overlap one another.

The plurality of photovoltaic elements 110 may include solar photovoltaic generation elements with different power generation characteristics. Of the plurality of photovoltaic elements 110, at least one may be a solar photovoltaic generation cell or a solar photovoltaic generation module, and at least one may be a solar photovoltaic generation string. Here, a solar photovoltaic generation cell is a basic unit of a solar cell, and a solar photovoltaic generation module is configured by connecting a plurality of solar photovoltaic generation cells in parallel. The solar photovoltaic generation cells may have a shape according to the location where they are arranged, and all of the plurality of solar photovoltaic generation cells do not have to have the same shape. On the other hand, the solar photovoltaic generation string is configured by connecting a plurality of solar photovoltaic generation cells or a plurality of solar photovoltaic generation modules in series. In the examples, the solar photovoltaic generation module and the solar photovoltaic generation string are each integrally configured components, and the connections between the solar photovoltaic generation cells in the solar photovoltaic generation module and the solar photovoltaic generation string are fixed and are not dynamically changed.

When the power generation output of the solar photovoltaic generation cell is 0.5 [V], the power generation output of the solar photovoltaic generation module is also 0.5 [V]. Therefore, in terms of output characteristics, the solar photovoltaic generation module can be regarded as a large-area solar photovoltaic generation cell. Therefore, for convenience of explanation, hereinafter, the solar photovoltaic generation cell and the solar photovoltaic generation module may be referred to as “solar photovoltaic generation cell” without distinction. If the number of solar photovoltaic generation cells connected in series in a solar photovoltaic generation string is N, the power generation output of the solar photovoltaic generation string is N×0.5 [V]. When N=6, the power generation output of the solar photovoltaic generation string is 3 [V]. In this way, the solar photovoltaic generation cells and the solar photovoltaic generation strings have different power generation outputs.

A solar photovoltaic generation cell generates power by electrons excited by irradiated light, and therefore the current that can flow depends on the amount of light irradiated onto the solar photovoltaic generation cell. Therefore, the larger the surface area of a solar photovoltaic generation cell, the more current it can carry. A solar photovoltaic generation string, which consists of a plurality of solar photovoltaic generation cells connected in series, can generate electricity efficiently if all solar photovoltaic generation cells are evenly exposed to light. However, if some solar photovoltaic generation cells are shaded, the amount of current generated in those cells will decrease, reducing the power generation efficiency of all solar photovoltaic generation cells. Therefore, it is preferable to place the solar photovoltaic generation string in an area that is less likely to be shaded.

Therefore, in the example, the solar photovoltaic generation string is provided in an area that is unlikely to be covered by a user's hand, and the solar photovoltaic generation cell is provided in an area that is likely to be covered by a user's hand. Since the user holds the two left and right gripping portions 80a and 80b with both hands, the central region of the housing 80 is relatively unlikely to be hidden by the user's hands, while the regions on both sides of the housing 80 are relatively likely to be hidden by the user's hands. Therefore, in an example, the photovoltaic elements 110a and 110f may be configured by a solar photovoltaic generation string, and the photovoltaic elements 110b, 110c, 110d, and 110e may be configured by a solar photovoltaic generation cell (or a solar photovoltaic generation module). Note that the photovoltaic element 110f may be configured by a solar photovoltaic generation cell (or a solar photovoltaic generation module) rather than a solar photovoltaic generation string.

The power generation control unit 100 may generate a relatively low voltage using a DC-DC converter that converts the voltage output from the solar photovoltaic generation cell, and may generate a relatively high voltage using a DC-DC converter that converts the voltage output from the solar photovoltaic generation string. Specifically, the power generation control unit 100 may use a DC-DC converter for a solar photovoltaic generation cell to store a voltage for a configuration (electronic component) driven at a relatively low voltage in the power storage unit 112, and use a DC-DC converter for a solar photovoltaic generation string to store a voltage for a configuration (electronic component) driven at a relatively high voltage in the power storage unit 112. In this way, the operation device 6 can easily generate a plurality of different voltages by mounting solar photovoltaic generation elements with different power generation outputs.

In the above example, solar photovoltaic generation cells and solar photovoltaic generation strings with different power generation outputs are shown as examples of solar photovoltaic generation elements with different power generation characteristics, but solar photovoltaic generation elements with different power generation characteristics may also be used from a different perspective. For example, of the plurality of solar photovoltaic generation elements arranged in the housing 80, at least one may be a solar photovoltaic generation element with a relatively low power generation efficiency, and at least one may be a solar photovoltaic generation element with a relatively high power generation efficiency. In general, solar photovoltaic generation elements with high power generation efficiency are expensive, while solar photovoltaic generation elements with low power generation efficiency are inexpensive. In this case, however, it is preferable to place the solar photovoltaic generation elements with high power generation efficiency in the central region of the housing 80, and the solar photovoltaic generation elements with low power generation efficiency in the regions on both sides of the housing 80.

The power generation control unit 100 monitors the power generation status of the plurality of photovoltaic elements 110. The power generation control unit 100 may monitor voltage and/or current in the plurality of photovoltaic elements 110. As described above, when the photovoltaic element 110 is shaded, the amount of power generated decreases. Therefore, the power generation control unit 100 can estimate whether the photovoltaic element 110 is shaded by monitoring the amount of power generated.

The connection circuit 114 is a circuit having the function of connecting any two or more of the photovoltaic elements 110 in series. For example, when the user is not holding the operation device 6 and the operation device 6 is placed on a desk with its top side facing up and is exposed to light, all the photovoltaic elements 110 generate power smoothly. At this time, the power generation control unit 100 controls the connection circuit 114 to dynamically connect two or more of the photovoltaic elements 110 in series. Specifically, a connection circuit 114 connects a plurality of designated photovoltaic elements 110 in series according to an instruction from a power generation control unit 100. Two or more of the photovoltaic elements 110 dynamically connected in series form a solar photovoltaic generation string, which can output a higher voltage than a single photovoltaic element 110. In this manner, the power generation control unit 100 may connect two or more of the photovoltaic elements 110 in series according to the monitored power generation state. The photovoltaic elements 110 to be connected in series are limited to those that are generating power efficiently, and if the amount of power generated by a certain photovoltaic element 110 is lower than normal, the power generation control unit 100 will not connect that photovoltaic element 110 in series.

For example, the power generation control unit 100 controls the connection circuit 114 and connects the four photovoltaic elements 110b, 110c, 110d, and 110e in series. In this case, the power generation control unit 100 can treat the series-connected photovoltaic elements 110b, 110c, 110d, and 110e as a four-stage solar photovoltaic generation string, and the power generation output is 2 (=4×0.5) [V].

FIG. 7 illustrates another example of a plurality of photovoltaic elements disposed in a housing. In the example illustrated in FIG. 7, the plurality of photovoltaic elements 110g, 100h, 100i, 100j, 100k, 100l, 100m, 100n, 1000, 100p, 100q, 100r, 100s, 100t, 100u, 100v, 100w, 100x, 100y, 100z (hereinafter simply referred to as “photovoltaic elements 110” when no particular distinction is made) are disposed on the upper surface of the housing 80 so as to efficiently receive light irradiation. One photovoltaic element 110 is a single component that is integrally formed, and the plurality of photovoltaic elements 110 are arranged on the top surface of the housing 80 so as not to overlap one another.

The plurality of photovoltaic elements 110 shown in FIG. 7 may include solar photovoltaic generation elements with different power generation characteristics, but in this example, the plurality of photovoltaic elements 110 may be solar photovoltaic generation cells or solar photovoltaic generation modules. As described above, because the solar photovoltaic generation module is configured by connecting a plurality of solar photovoltaic generation cells in parallel, the power generation output (voltage) of the solar photovoltaic generation module is equal to the power generation output of the solar photovoltaic generation cell. In FIG. 7, the light receiving areas (surface areas) of the plurality of photovoltaic elements 110 are not uniform, but the photovoltaic elements 110 may be formed so that the light receiving areas are equal.

The power generation control unit 100 monitors the power generation status of the plurality of photovoltaic elements 110. The power generation control unit 100 may control the connection circuit 114 to dynamically and serially connect two or more of the photovoltaic elements 110 that generate power efficiently. By connecting two or more of the photovoltaic elements 110 in series, a voltage higher than that of the photovoltaic element 110 alone can be output. When the power generation state changes, the power generation control unit 100 may dynamically change the combination of two or more of the photovoltaic elements 110 connected in series.

FIG. 8 illustrates another example of a plurality of photovoltaic elements disposed in a housing. One photovoltaic element 110 is a single component that is integrally formed, and the plurality of photovoltaic elements 110 are arranged on the top surface of the housing 80 so as not to overlap one another. In the example shown in FIG. 8, the photovoltaic element 110 is an inverted U-shaped solar photovoltaic generation cell or module that extends from near the end of the left gripping portion 80a to near the end of the right gripping portion 80b. When a user holds the left gripping portion 80a and the right gripping portion 80b, part of the light receiving area is covered by the hand, but since it is unlikely that the entire light receiving area will be covered by the hand, the photovoltaic element 110 having a long and narrow light receiving area has the advantage of being able to maintain power generation output (voltage). The power generation control unit 100 may control the connection circuit 114 and connect two or more of the photovoltaic elements 110 in series.

Another method for connecting two or more of the photovoltaic elements 110 in series will be described below. The server device collects operation information of the operation device 6 for each game from the information processing devices 10 used by a plurality of users. By collecting operation information of the operation device 6, the server device can distinguish between operators that are frequently used during game play and operators that are not used often. Here, the area around a frequently used operator means an area that is likely to be hidden by the user's hand during game play (an area where it is difficult to generate power), and the area around an infrequently used operator means an area that is unlikely to be hidden by the user's hand during game play (an area where it is easy to generate electricity).

When starting a game, the information processing device 10 acquires information indicating operators that are not often used in the game from the server device. The information processing device 10 identifies the position on the top surface of the housing where an operator that is not often used is located, and determines that the power generation efficiency around that position is high. For example, if photovoltaic elements 110 are arranged on the front of the housing of the controller device 6 as shown in FIG. 7, the information processing device 10 identifies two or more of the photovoltaic elements 110 that are predicted to have high power generation efficiency during game play, and sends instructions to the operation device 6 to connect the identified two or more of the photovoltaic elements 110. This connection instruction will depend on the game to be played.

In the operation device 6, when the wireless communication unit 86 receives an instruction regarding the connection of two or more of the photovoltaic elements 110, the power generation control unit 100 connects the two or more of the photovoltaic elements 110 in series in accordance with the received instruction. After connecting the photovoltaic elements 110 in series in accordance with the instruction, the power generation control unit 100 may dynamically change the combination of the photovoltaic elements 110 to be connected in series in accordance with the power generation status of each photovoltaic element 110, as described above.

The present disclosure has been described above based on an example. The present example is one example, and it is understood by those having ordinary skill in the art that various variations are possible in the combination of the respective constituent elements or respective processing processes, and that such variations are also within the scope of the present disclosure. In the example, it is assumed that the user is playing a game, but applications other than games may also be implemented.

In an example, the server device distinguishes between commonly used operators and rarely used operators for each game. In the modified example, the information processing device 10 may specify frequently used operators and infrequently used operators for each game. Furthermore, the information processing device 10 may statistically analyze and find not only during the game play but also operators frequently used by the user and operators not frequently used by the user. For example, if a user uses the left analog stick 72a but does not use the directional keys 70, the information processing device 10 may identify the directional keys 70 as an operator that the user does not use often.

In the example, it has been explained that the operation device 6 is not equipped with a secondary battery that is charged by an external power source or a primary battery, but in a modified example, the operation device 6 may be equipped with a secondary battery that is charged by an external power source and/or a primary battery as an auxiliary power source. For example, the power generation control unit 100 may use the power of the power storage unit 112 as long as the power storage unit 112 does not run out of power, and may use an auxiliary power source when the power storage unit 112 runs out of power.

The present disclosure can be used in the technical field of user-operated electronic devices.

1: Information processing system, 6: Operation device, 10: Information processing device, 70: Directional key, 71: Action button, 72a: Left analog stick, 72b: Right analog stick, 73: Touchpad, 80: Housing, 80a: Left gripping portion, 80b: Right gripping portion, 80c: Housing main body portion, 86: Wireless communication unit, 90: Processing unit, 91: Control unit, 92: Input reception unit, 93: Sensor data acquisition unit, 94: Audio output unit, 95: Audio input unit, 96: Driving unit, 96a: First driving unit, 96b: Second driving unit, 97: Driving unit, 97a: Third driving unit, 97b: Fourth driving unit, 100: Power generation control unit, 110: Photovoltaic element, 112: Power storage unit, 114: Connection circuit.

What is claimed is:

1. An operation device equipped with a gripping portion that a user holds with a hand and an input unit that the user operates, the operation device comprising:
a plurality of photovoltaic elements disposed in a housing; and
a power storage unit that stores power generated by the plurality of photovoltaic elements.

2. The operation device of claim 1, wherein the plurality of photovoltaic elements comprises solar photovoltaic generation elements having different power generation characteristics.

3. The operation device of claim 2, wherein the plurality of photovoltaic elements comprises solar photovoltaic generation elements with different power generation outputs.

4. The operation device of claim 3, wherein at least one of the plurality of solar photovoltaic generation elements is a solar photovoltaic generation cell or a solar photovoltaic generation module, and at least one is a solar photovoltaic generation string in which a plurality of solar photovoltaic generation cells or a plurality of solar photovoltaic generation modules are connected in series.

5. The operation device of claim 2, wherein at least one from among the plurality of solar photovoltaic generation elements is a solar photovoltaic generation element with a relatively low power generation efficiency and at least one is a solar photovoltaic generation element with a relatively high power generation efficiency.

6. The operation device of claim 1, further comprising a power generation control unit that connects two or more of the photovoltaic elements in series.

7. The operation device of claim 6, wherein the power generation control unit monitors a power generation state of the photovoltaic elements and connects two or more of the photovoltaic elements in series according to the power generation state.

8. The operation device of claim 6, further comprising:
a communication unit that transmits operation information obtained through a user operating the input unit to an external information processing device,
wherein the communication unit receives instructions regarding the connection of two or more of the photovoltaic elements from the information processing device, and the power generation control unit connects the two or more of the photovoltaic elements in series in accordance with the received instructions.

9. The operation device of claim 8, wherein the eternal information processing device comprises a video game console.

10. The operation device of claim 8, wherein the information processing device generates the instruction according to an application to be executed.

11. A method comprising:
equipping an operation device with (i) a gripping portion that a user holds with a hand and (ii) an input unit that the user operates;
providing a plurality of photovoltaic elements in a housing of the operation device; and
disposing, in the housing of the operation device, a power storage unit that stores power generated by the plurality of photovoltaic elements.

12. The method of claim 11, wherein the plurality of photovoltaic elements comprises solar photovoltaic generation elements having different power generation characteristics.

13. The method of claim 12, wherein the plurality of photovoltaic elements comprises solar photovoltaic generation elements with different power generation outputs.

14. The method of claim 13, wherein at least one of the plurality of solar photovoltaic generation elements is a solar photovoltaic generation cell or a solar photovoltaic generation module, and at least one is a solar photovoltaic generation string in which a plurality of solar photovoltaic generation cells or a plurality of solar photovoltaic generation modules are connected in series.

15. The method of claim 12, wherein at least one from among the plurality of solar photovoltaic generation elements is a solar photovoltaic generation element with a relatively low power generation efficiency and at least one is a solar photovoltaic generation element with a relatively high power generation efficiency.

16. The method of claim 11, further comprising disposing, in the housing of the operation device, a power generation control unit that connects two or more of the photovoltaic elements in series.

17. The method of claim 16, wherein the power generation control unit monitors a power generation state of the photovoltaic elements and connects two or more of the photovoltaic elements in series according to the power generation state.

18. The method of claim 16, further comprising:
disposing, in the housing of the operation device, a communication unit that transmits operation information obtained through a user operating the input unit to an external information processing device,
wherein the communication unit receives instructions regarding the connection of two or more of the photovoltaic elements from the information processing device, and the power generation control unit connects the two or more of the photovoltaic elements in series in accordance with the received instructions.

19. The method of claim 18, wherein the eternal information processing device comprises a video game console.

20. The method of claim 18, wherein the information processing device generates the instruction according to an application to be executed.
